(19) United States
(12) Patent Application Publication
(10) Pub. No.: US 2013/0075750 A1
(43) Pub. Date: Mar. 28, 2013

(54) SEMICONDUCTOR DEVICE

(71) Applicant: Yuichi MINOURA, Zama (JP)

(72) Inventor: Yuichi MINOURA, Zama (JP)

(73) Assignee: FUJITSU LIMITED, Kawasaki-shi (JP)

(21) Appl. No.: 13/572,806

(22) Filed: Aug. 13, 2012

(30) Foreign Application Priority Data
Sep. 27, 2011 (JP) 2011-211560

(51) Int. Cl. H01L 29/78; H01L 21/20

(52) U.S. Cl. 257/76; 438/478; 257/E29.255; 257/E21.09

(57) ABSTRACT

A semiconductor device includes a first semiconductor layer formed on a substrate; a second semiconductor layer formed on the first semiconductor layer; a third semiconductor layer formed on the second semiconductor layer; a gate electrode formed on the third semiconductor layer; and a source electrode and a drain electrode formed on the second semiconductor layer. The third semiconductor layer is formed with a semiconductor material doped with a p-type impurity element. In the third semiconductor layer, a p-type area is formed immediately below the gate electrode, and a high resistance area having a higher resistance than the p-type area is formed in an area other than the p-type area.

### CROSS-REFERENCE TO RELATED APPLICATION

This patent application is based upon and claims the benefit of priority of the prior Japanese Patent Application No. 2011-211560 filed on Sep. 27, 2011, the entire contents of which are incorporated herein by reference.

### FIELD

The embodiments discussed herein are related to a semiconductor device and a method of manufacturing the semiconductor device.

### BACKGROUND

GaN, AlN, InN, which are nitride semiconductors, or materials made of mixed crystals thereof, have a wide band gap, and are used as high output electronic devices or short-wavelength light emitting devices. Among these, as high output electronic devices, technologies are developed in relation to Field effect transistors (FET), more particularly, High Electron Mobility Transistors (HEMT) (see, for example, Japanese Laid-Open Patent Publication No. 2002-359256). A HEMT using such a nitride semiconductor is used for high output/high efficiency amplifiers and high power switching devices.

Incidentally, high output/high efficiency amplifiers and switching devices are demanded to have normally-off characteristics. The normally-off state is important in terms of performing safe operations. However, in a HEMT using GaN, the density of electrons is high in 2DEG (Two-Dimensional Electron Gas) generated in the electron transit layer due to the effect of piezo polarization and spontaneous polarization in GaN, and therefore it is difficult to attain the normally-off state. Various methods are being considered for attaining the normally-off state in a HEMT using GaN.

One of these methods is a method of forming a p-GaN layer immediately below the gate electrode. Specifically, as illustrated in FIG. 1, on a substrate 911 such as SiC, a buffer layer 912, an electron transit layer 913, and an electron supply layer 914 are formed. On the electron supply layer 914 and immediately below a gate electrode 921, a p-GaN layer 915 is formed. The buffer layer 912 is formed with AlN, the electron transit layer 913 is formed with i-GaN, and the electron supply layer 914 is formed with i-AlGaN or n-AlGaN. On the electron supply layer 914, a source electrode 922 and a drain electrode 923 are formed.

In the HEMT having such a structure, in the electron transit layer 913, 2DEG 913a is formed near the interface between the electron supply layer 914 and the electron transit layer 913. However, in an area 913b immediately below the gate electrode 921, the electrons of the 2DEG 913a disappear. That is to say, by forming the p-GaN layer 915 immediately below the area where the gate electrode 921 is formed, the conduction band is lifted up. Therefore, only in the area 913b immediately below the gate electrode 921, the electrons in the 2DEG 913a disappear. Accordingly, while preventing the on-resistance from increasing, it is possible to attain a normally-off state.

Non-Patent document 1: S.Nakamura et.al., Jpn. J. Appl. Phys., 31(1992), p.1258

The HEMT having the structure illustrated in FIG. 1 is manufactured by procedures illustrated in FIGS. 2A and 2B.

First, as illustrated in FIG. 2A, on the substrate 911 such as SIC, the buffer layer 912, the electron transit layer 913, the electron supply layer 914, and a p-GaN film 915a are formed.

Next, as illustrated in FIG. 2B, on the surface of the p-GaN film 915a, a resist pattern 931 is formed in an area where the gate electrode 921 is to be formed, and dry etching is performed.

Next, as illustrate in FIG. 2C, dry etching is performed to remove the p-GaN film 915a in the area where the resist pattern 931 is not formed, and then the resist pattern 931 is removed. Accordingly, on the electron supply layer 914, the p-GaN layer 915 is formed in the area where the gate electrode 921 is to be formed. By forming the p-GaN layer 915, it is possible to form the 2DEG 913a in the electron transit layer 913 near the interface between the electron supply layer 914 and the electron transit layer 913, having the area 913b where electrons disappear immediately below the p-GaN layer 915.

Next, as illustrated in FIG. 3, the gate electrode 921 is formed on the p-GaN layer 915, and a source electrode 922 and a drain electrode 923 are formed on the electron supply layer 914.

In this manufacturing procedure, as illustrated in FIG. 2B, it is very difficult to completely remove by dry etching, the p-GaN film 915a only in the area where the resist pattern 931 is not formed. Specifically, as illustrated in FIG. 4A, there are cases where a thin p-GaN film 915b remains in the area other the area immediately below the gate electrode 921. Furthermore, as illustrated in FIG. 4B, there are cases where part of the electron supply layer 914 is removed by etching in the area other than the area immediately below the gate electrode 921. As illustrated in FIG. 4A, when the thin p-GaN film 915b remains in the area other than the area immediately below the gate electrode 921, due to the remaining thin p-GaN film 915b, the density of electrons in the 2DEG 913a decreases, and therefore the on-resistance increases. Furthermore, as illustrated in FIG. 4B, part of the electron supply layer 914 is removed in the area other than the area immediately below the gate electrode 921, the thickness of the electron supply layer 914 is reduced, and the density of electrons in the 2DEG 913a decreases, and therefore the on-resistance increases.

Accordingly, in the HEMT using GaN, when the p-GaN layer 915 is formed immediately below the gate electrode 921, it is difficult to attain a normally-off state without increasing the on-resistance.

### SUMMARY

According to an aspect of the embodiments, a semiconductor device includes a first semiconductor layer formed on a substrate; a second semiconductor layer formed on the first semiconductor layer; a third semiconductor layer formed on the second semiconductor layer; a gate electrode formed on the third semiconductor layer; and a source electrode and a drain electrode formed on the second semiconductor layer, wherein the third semiconductor layer is formed with a semiconductor material doped with a p-type impurity element, and in the third semiconductor layer, a p-type area is formed immediately below the gate electrode, and a high resistance area having a higher resistance than the p-type area is formed in an area other than the p-type area.

The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 illustrates a conventional HEMT using GaN;

FIGS. 2A through 2C illustrate procedures of a manufacturing method of a conventional HEMT using GaN (part 1);

FIG. 3 illustrates procedures of the manufacturing method of the conventional HEMT using GaN (part 2);

FIGS. 4A and 4B describe a conventional HEMT using GaN;

FIG. 5 illustrates a semiconductor device according to a first embodiment;

FIGS. 6A through 6C illustrate procedures of a manufacturing method of the semiconductor device according to the first embodiment (part 1);

FIGS. 7A through 7C illustrate procedures of the manufacturing method of the semiconductor device according to the first embodiment (part 2);

FIGS. 8A through 8C illustrate procedures of the manufacturing method of the semiconductor device according to the first embodiment (part 3);

FIG. 9 illustrates a semiconductor device according to a second embodiment;

FIGS. 10A through 10C illustrate procedures of a manufacturing method of a semiconductor device according to the second embodiment;

FIGS. 11A through 11C illustrate procedures of a manufacturing method of a semiconductor device according to a third embodiment (part 1);

FIGS. 12A through 12C illustrate procedures of the manufacturing method of the semiconductor device according to the third embodiment (part 2);

FIG. 13 illustrates procedures of the manufacturing method of the semiconductor device according to the third embodiment (part 3);

FIG. 14 illustrates procedures of a manufacturing method of a semiconductor device according to a fourth embodiment;

FIGS. 15A through 15C illustrate procedures of a manufacturing method of a semiconductor device according to a fourth embodiment (part 1);

FIGS. 16A through 16C illustrate procedures of the manufacturing method of the semiconductor device according to the fourth embodiment (part 2);

FIGS. 17A through 17C illustrate procedures of the manufacturing method of the semiconductor device according to the fourth embodiment (part 3);

FIG. 18 illustrates procedures of the manufacturing method of the semiconductor device according to the fourth embodiment (part 4);

FIG. 19 illustrates a discretely packaged semiconductor device according to a fifth embodiment;

FIG. 20 illustrates a power unit according to the fifth embodiment; and

FIG. 21 illustrates a high-frequency amplifier according to the fifth embodiment.

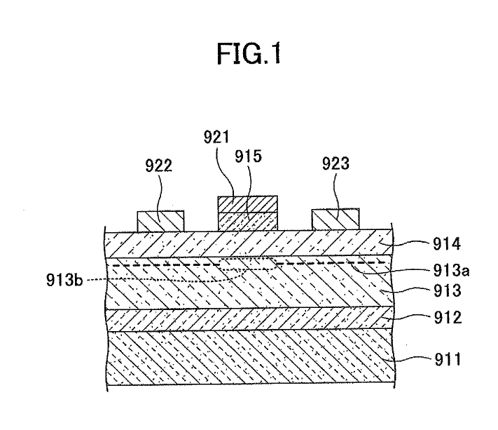

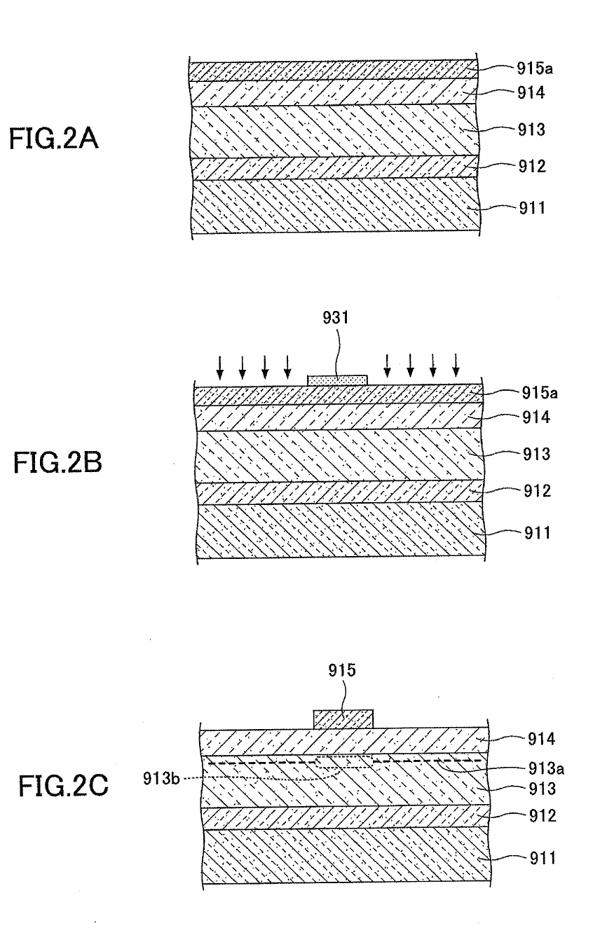

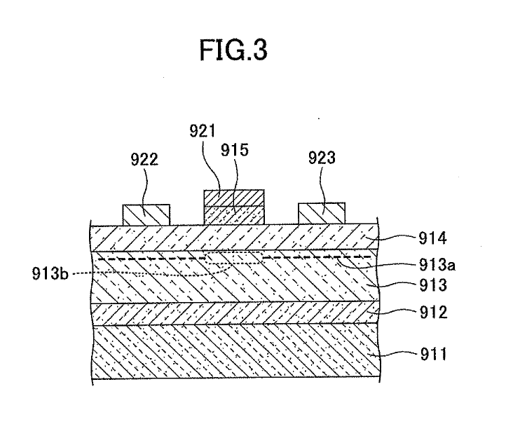

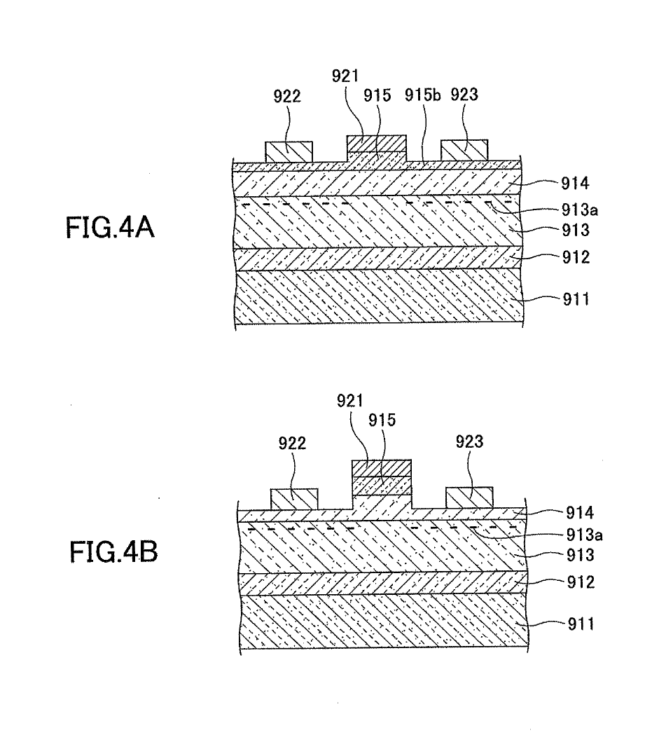

### DESCRIPTION OF EMBODIMENTS

Preferred embodiments of the present invention will be explained with reference to accompanying drawings. The same elements are denoted by the same reference numerals and overlapping descriptions are omitted.

### First Embodiment

### Semiconductor Device

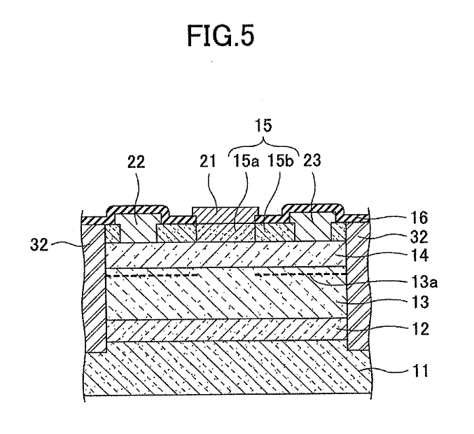

A description is given of a semiconductor device according to the present embodiment with reference to FIG. 5. In the semiconductor device according to the present embodiment, on a substrate 11, a buffer layer 12 that is a nitride semiconductor, an electron transit layer 13, and an electron supply layer 14 are formed. On the electron supply layer 14, a Mg doped GaN layer 15 is formed, which is a nitride semiconductor layer doped with a p-type impurity material. A gate electrode 21 is formed on the Mg doped GaN layer 15, and a source electrode 22 and a drain electrode 23 are formed on the electron supply layer 14. Furthermore, on the Mg doped GaN layer 15, the source electrode 22, the drain electrode 23, and a passivation film 16 formed with SiN are formed. In the semiconductor device according to the present embodiment, an element separation area 32 for separating the respective elements is formed, from the surface of the substrate 11 through the buffer layer 12, the electron transit layer 13, the electron supply layer 14, and the Mg doped GaN layer 15.

In the Mg doped GaN layer 15, a p-GaN area 15a that is a p-type area and a high resistance area 15b are formed, and the p-GaN area 15a is formed immediately below the gate electrode 21. In the Mg doped GaN layer 15, the hydrogen density is decreased as described below in the p-GaN area 15a. Accordingly, the Mg doped GaN layer 15 is activated to a p-type by the doped Mg. However, in the high resistance area 15b, the hydrogen density is high and Mg is bound with H, and therefore the resistance is high. Thus, in the electron transit layer 13, near the interface between the electron transit layer 13 and the electron supply layer 14, a 2DEG 13a is formed. However, it is possible to make the electrons disappear only immediately below the p-GaN area 15a, without decreasing the density of electrons immediately below the high resistance area 15b. That is to say, it is possible to form the 2DEG 13a in which electrons are made to disappear only immediately below the gate electrode 21, without decreasing the density of electrons immediately below the area where the gate electrode 21 is not formed. Accordingly, in the semiconductor device according to the present embodiment, a normally-off state is attained without increasing the on-resistance.

In the present embodiment, the area immediately below the p-GaN area 15a includes the area across the electron supply layer 14, and the area immediately below the gate electrode 21 includes the area across the p-GaN area 15a and the electron supply layer 14.

Therefore, as described above, in the semiconductor device according to the present embodiment, in the Mg doped GaN layer 15, the hydrogen density is higher in the high resistance area 15b than in the p-GaN area 15a, and the electric resistance is higher in the high resistance area 15b than in the p-GaN area 15a.

### First Embodiment

### Manufacturing Method of Semiconductor Device

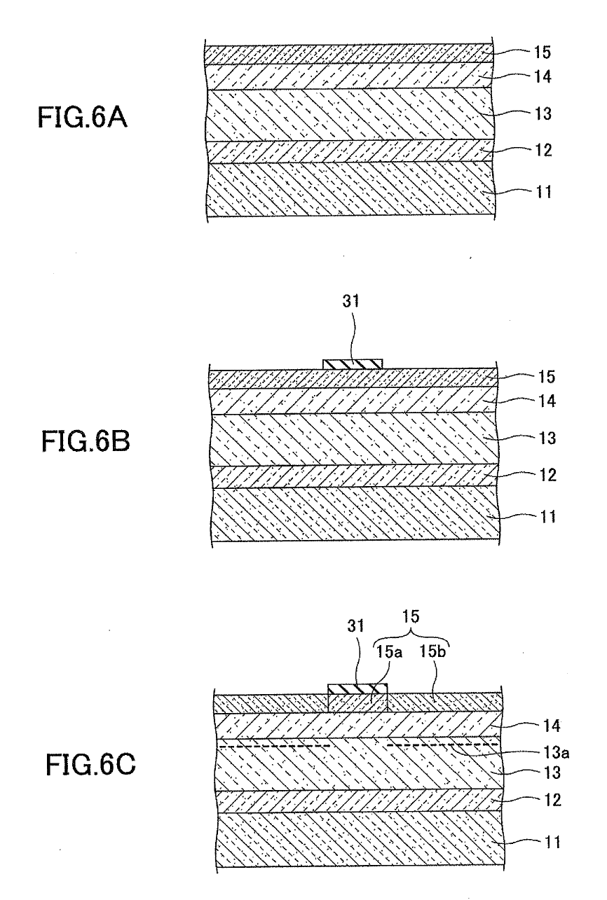

A description is given of the manufacturing method of the semiconductor device according to the first embodiment with reference to FIGS. 6A through 8C.

First, as illustrated in FIG. 6A, on the substrate 11, nitride semiconductor layers including the buffer layer 12, the electron transit layer 13, the electron supply layer 14, and the Mg doped GaN layer 15 are formed by epitaxial growth by a MOVPE (Metal Organic Vapor Phase Epitaxy) method. In the present embodiment, the buffer layer 12 is formed with AlN, the electron transit layer 13 is formed with GaN, and the electron supply layer 14 is formed with AlGaN.

When forming the nitride semiconductor layers by MOVPE, TMA (trimethyl aluminium) is used as the raw material gas of Al, TMG (trimethyl gallium) is used as the raw material gas of Ga, and NH₃ (ammonia) is used as the raw material gas of N. Furthermore, Cp₂Mg (cyclopentadienyl magnesium) is used as the raw material gas of Mg. The raw material gas described above is supplied to a reacting furnace of a MOVPE device by using hydrogen (H₂) as carrier gas.

The ammonia gas supplied when forming the nitride semiconductor layers is supplied by a flow rate of 100 sccm through 10000 sccm, the growth pressure when the nitride semiconductor layer is formed is 50 Torr through 300 Torr, and the growth temperature is 1000° C. through 1200° C. The nitride semiconductor layers may be formed by MBE (Molecular Beam Epitaxy) instead of MOVPE.

As the substrate 11, for example, a sapphire substrate, a Si substrate, and a SiC substrate may be used. In the present embodiment, a SiC substrate is used as the substrate 11. The buffer layer 12 is formed with AlN having a thickness of 0.1 μm. The electron transit layer 13 is formed with GaN having a thickness of 2 μm.

The electron supply layer 14 is formed with AlGaN having a thickness of 20 nm, which is expressed as AlₓGa₁₋ₓN, where X is 0.1 through 0.3.

The electron supply layer 14 may be i-AlGaN or n-AlGaN. When forming n-AlGaN, Si is doped as an impurity element, so that the density of Si is 1×10¹⁸ cm⁻³ through 1×10²⁰ cm⁻³, for example 1×10¹⁹ cm⁻³. The raw material gas of Si, is for example, SiH₄.

The Mg doped GaN layer 15 has a thickness of 5 nm through 150 nm, which is formed with GaN doped with Mg as the impurity element, so that the density of the impurity element is 5×10¹⁸ cm⁻³ through 5×10²⁰ cm⁻³. In the present embodiment, the Mg doped GaN layer 15 has a thickness of 50 nm, and is doped with Mg as the impurity element so that the density of the impurity element is 1×10¹⁹ cm⁻³.

After forming the nitride semiconductor layers by MOVPE, a heating process is performed with a temperature of, for example, 400° C. through 1000° C., in a nitride atmosphere. Accordingly, the Mg doped GaN layer 15 is activated. By performing a heating process in a nitride atmosphere as described above, the hydrogen components included in the Mg doped GaN layer 15 are discharged and the Mg doped GaN layer 15 is activated, so that the Mg doped GaN layer 15 becomes a p-type.

Next, as illustrated in FIG. 6B, on the surface of the Mg doped GaN layer 15, a dielectric mask 31 is formed in the area where the gate electrode 21 is to be formed. Specifically, on the surface of the Mg doped GaN layer 15, a dielectric film such as SiN or SiO₂ is formed, photoresist is applied on the dielectric film, and exposure and developing are performed with an exposing device, thereby forming a resist pattern (not illustrated) in the area where the gate electrode 21 is to be formed. Subsequently, the dielectric film in the area where the resist pattern is not formed is removed by performing wet etching using fluorine, thereby forming the dielectric mask 31 formed with

SiN or SiO₂. Subsequently, the resist pattern is removed with an organic solvent.

Next, as illustrated in FIG. 6C, a heating process is performed with a temperature of greater than or equal to 400° C., in an atmosphere of H₂ or NH₃. Accordingly, in the area where the dielectric mask 31 is not formed such that the Mg doped GaN layer 15 is exposed, H₂ or H in NH₃ enters the Mg doped GaN layer 15 and diffuses. As described above, in the Mg doped GaN layer 15, H diffuses in the area where the dielectric mask 31 is not formed, and the diffused H (hydrogen) bonds with Mg and becomes Mg—H, and therefore the Mg does not function as an accepter and the resistance increases. Therefore, in the Mg doped GaN layer 15, the high resistance area 15b with high resistance where the dielectric mask 31 is not formed, and the dielectric mask 31 are formed, and the p-GaN area 15a that is maintained in an activated state where H has not entered is also formed.

As described above, by forming the high resistance area 15b in the Mg doped GaN layer 15, it is possible to form the 2DEG 13a in the electron transit layer 13 near the interface between the electron transit layer 13 and the electron supply layer 14, without decreasing the electron density immediately below the high resistance area 15b. In the 2DEG 13a formed as described above, electrons disappear immediately below the p-GaN area 15a of the Mg doped GaN layer 15.

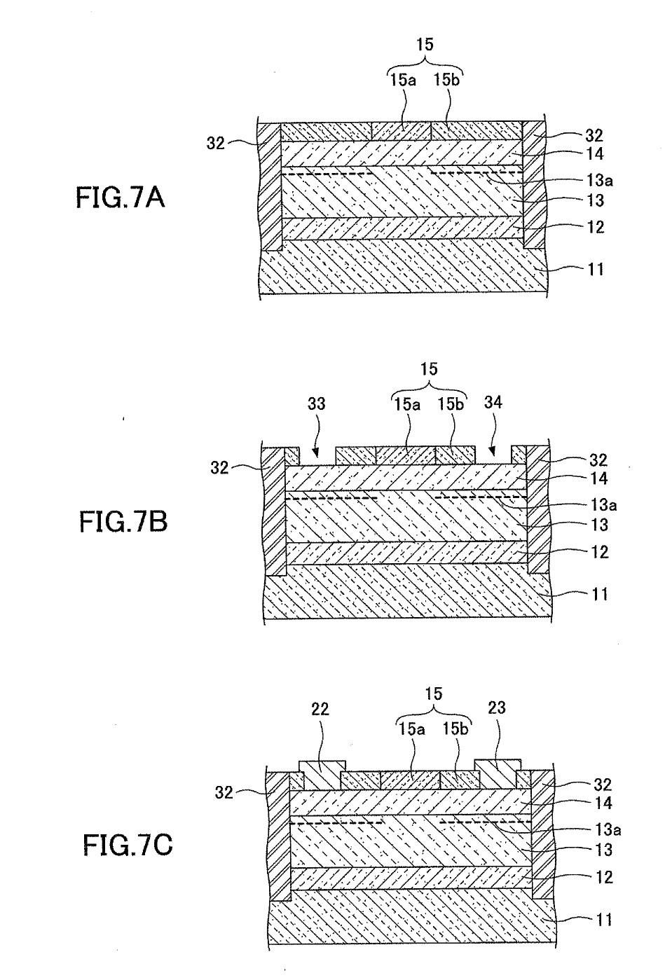

Next, as illustrated in FIG. 7A, after removing the dielectric mask 31, an element separation area 32 is formed. Specifically, after removing the dielectric mask 31, photoresist is applied to the surface of the Mg doped GaN layer 15, and exposure and developing are performed with an exposing device, thereby forming a resist pattern (not illustrated) having an opening in the area where the element separation area 32 is to be formed. Subsequently, by ion-implanting Ar in the nitride semiconductor layers in the area where the resist pattern is not formed, it is possible to form the element separation area 32 on the surfaces of the nitride semiconductor layers and the substrate 11. Subsequently, the resist pattern is removed with an organic solvent.

Next, as illustrated in FIG. 7B, the Mg doped GaN layer 15 is removed from the areas where the source electrode 22 and the drain electrode 23 are to be formed, so that openings 33 and 34 are formed. Specifically, photoresist is applied on the surface of the Mg doped GaN layer 15, and exposure and developing are performed with an exposing device, thereby forming a resist pattern (not illustrated) having openings in the areas where the openings 33 and 34 are to be formed. Subsequently, by performing dry etching such as RIE (Reactive Ion Etching), the Mg doped GaN layer 15 is removed from areas where the resist pattern is not formed, so that the openings 33 and 34 are formed. At this time, dry etching may be performed by using chlorinated gas such as Cl₂ as etching gas to completely remove the Mg doped GaN layer 15 in the areas where the resist pattern is not formed. Furthermore, part of the surface of the electron supply layer 14 may also be removed. Subsequently, the resist pattern is removed with an organic solvent.

Next, as illustrated in FIG. 7C, the source electrode 22 and the drain electrode 23 are formed in the openings 33 and 34. Specifically, photoresist is applied on the Mg doped GaN layer 15 with the openings 33 and 34, and exposure and developing are performed with an exposing device, thereby forming a resist pattern (not illustrated) having openings in the area where the source electrode 22 and the drain electrode 23 are to be formed. This resist pattern is formed by matching the positions of the openings of the resist pattern with the openings 33 and 34. Subsequently, by vacuum deposition, a laminated metal film is formed with Ti/Al, and then by dipping the laminated metal film in an organic solvent, the metal film formed on the resist pattern is removed by being lifted off together with the resist pattern. Accordingly, the source electrode 22 and the drain electrode 23 are formed, in which Ti/Al is laminated. In the laminated metal layer formed with Ti/Al, Ti has a thickness of approximately 20 nm, and Al has a thickness of approximately 200 nm. Subsequently, for example, a heating process is performed at a temperature of approximately 550° C. in a nitride atmosphere, and the source electrode 22 and the drain electrode 23 are made to contact the electron supply layer 14 by Ohmic Contact.

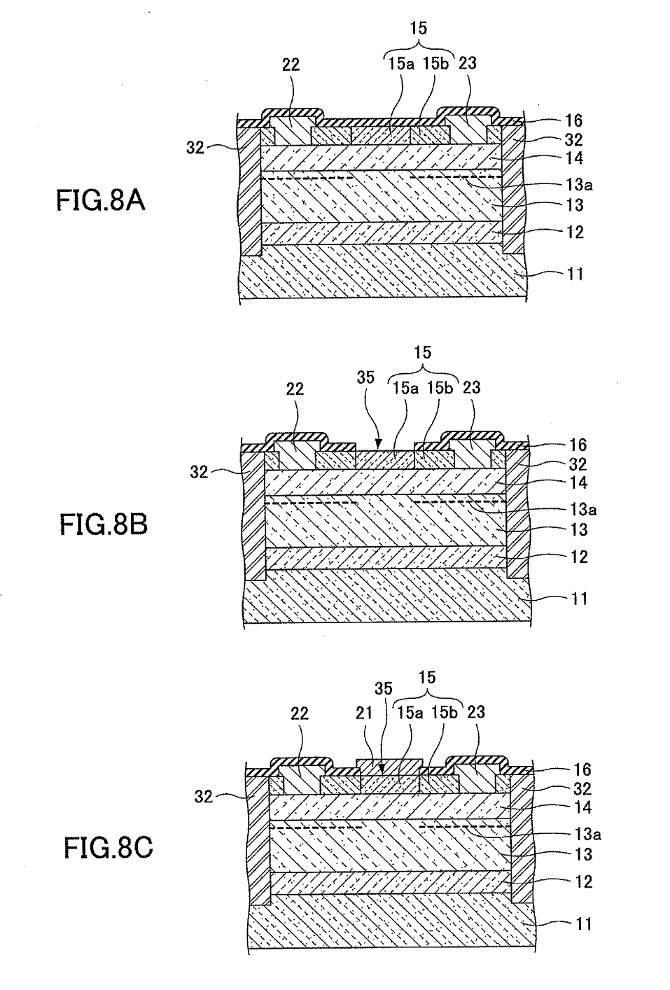

Next, as illustrated in FIG. 8A, the passivation film 16 is formed on the Mg doped GaN layer 15. The passivation film 16 is formed by forming SiN having a thickness of 200 nm by CVD (Chemical Vapor Deposition).

Next, as illustrated in FIG. 8B, the passivation film 16 is removed from the area where the gate electrode 21 is formed, and an opening 35 is formed. The opening 35 is formed in the area where the gate electrode 21 is to be formed. Specifically, photoresist is applied on the surface of the passivation film 16, and exposure and developing are performed with an exposing device, thereby forming a resist pattern (not illustrated) having an opening in the area where the opening 35 is to be formed. Subsequently, by performing dry etching such as RIE, or by performing wet etching with Buffered Hydrogen Fluoride, the passivation film 16 in the area where the resist pattern is not formed is removed, so that the opening 35 is formed. Subsequently, the resist pattern is removed with an organic solvent. The opening 35 is formed preferably to substantially match the p-GaN area 15a, but may be larger or smaller than the p-GaN area 15a.

Next, as illustrated in FIG. 8C, the gate electrode 21 is formed. Specifically, photoresist is applied on the surface of the passivation film 16 in which the opening 35 is formed, and exposure and developing are performed with an exposing device, thereby forming a resist pattern (not illustrated) having an opening in the area where the gate electrode 21 is to be formed. The resist pattern is formed by matching the position of the opening of the resist pattern with the opening 35, i.e., the p-GaN area 15a. Subsequently, by vacuum deposition, a laminated metal film is formed with Ni/Au, and then by dipping the laminated metal film in an organic solvent, the metal film formed on the resist pattern is removed by being lifted off together with the resist pattern. Accordingly, the gate electrode 21 is formed with the laminated metal film made of Ni/Au. The gate electrode 21 is formed on the p-GaN area 15a in the Mg doped GaN layer 15. The laminated metal film made of Ni/Au is formed so that the thickness of Ni is approximately 30 nm and the thickness of Au is approximately 400 nm.

As described above, the semiconductor device according to the present embodiment is manufactured. In the semiconductor device according to the present embodiment, in the Mg doped GaN layer 15, the p-GaN area 15a and the high resistance area 15b are formed. In the Mg doped GaN layer 15, the high resistance area 15b is not activated and is highly resistant, and therefore the density of electrons in the 2DEG 13a immediately below the high resistance area 15b does not decrease. Furthermore, in the Mg doped GaN layer 15, the p-GaN area 15a immediately below the gate electrode 21 is activated to a p-type, and therefore immediately below the p-GaN area 15a, the electrons of the 2DEG 13a disappear. That is to say, in the present embodiment, the electrons of the 2DEG 13a disappear immediately below the gate electrode 21. Accordingly, in the semiconductor device according to the present embodiment, a normally-off state is attained without increasing the on-resistance.

In the Mg doped GaN layer 15 of the semiconductor device according to the present embodiment, in the high resistance area 15b, the H and Mg included in the film are bound together and the resistance is increased, while in the p-GaN area 15a, the H included in the film is discharged so that the film becomes p-type. Accordingly, the density of hydrogen is higher in the high resistance area 15b than in the p-GaN area 15a, and the electric resistance is higher in the high resistance area 15b than in the p-GaN area 15a.

### Second Embodiment

### Semiconductor Device

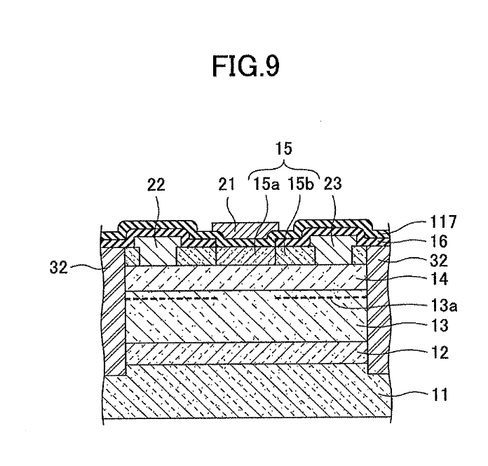

Next, a description is given of a semiconductor device according to a second embodiment with reference to FIG. 9. In the semiconductor device according to the present embodiment, on a substrate 11, a buffer layer 12 that is a nitride semiconductor, an electron transit layer 13, and an electron supply layer 14 are formed. On the electron supply layer 14, a Mg doped GaN layer 15 is formed, which is a nitride semiconductor layer doped with a p-type impurity material. A source electrode 22 and a drain electrode 23 are formed on the electron supply layer 14, and a passivation film 16 formed with SiN is formed on the Mg doped GaN layer 15, the source electrode 22, and the drain electrode 23. In the passivation film 16, an opening is formed in the area where the gate electrode 21 is to be formed. On the passivation film 16 and the Mg doped GaN layer 15 at the opening, an insulating film 117 to be a gate insulating film is provided. The gate electrode 21 is formed on the p-GaN area 15a of the Mg doped GaN layer 15 via the insulating film 117. That is to say, in the Mg doped GaN layer 15, the p-GaN area 15a and the high resistance area 15b that becomes the p-type area are formed, and the p-GaN area 15a is formed immediately below the gate electrode 21 via the insulating film 117. In the semiconductor device according to the present embodiment, an element separation area 32 for separating the elements is formed from the surface of the substrate 11 through the buffer layer 12, the electron transit layer 13, the electron supply layer 14, and the Mg doped GaN layer 15.

In the Mg doped GaN layer 15, the hydrogen density is decreased as described below in the p-GaN area 15a. Accordingly, the p-GaN area 15a is activated to a p-type due to the doped Mg. However, in the high resistance area 15b, the hydrogen density is high, and Mg is bound with H, and therefore the high resistance area 15b becomes highly resistant. Accordingly, in the electron transit layer 13, the 2DEG 13a is formed near the interface between the electron transit layer 13 and the electron supply layer 14. However, the electrons are made to disappear only immediately below the p-GaN area 15a, without decreasing the density of electrons immediately below the high resistance area 15b. That is to say, it is possible to form the 2DEG 13a in which the electrons are made to disappear only immediately below the gate electrode 21, without decreasing the density of electrons immediately below the area where the gate electrode 21 is not formed. Therefore, in the semiconductor device according to the present embodiment, a normally-off state is attained without increasing the on-resistance.

Accordingly, in the semiconductor device according to the present embodiment, it is possible to suppress a gate leak current by forming the insulating film 117, and the withstand pressure in the forward direction is increased in the gate electrode 21. Therefore, it is possible to increase the voltage applied to the gate electrode 21 during the on operation, so that a larger amount of drain current flows. As described above, in the semiconductor device according to the present embodiment, in the Mg doped GaN layer 15, the hydrogen density is higher in the high resistance area 15b than in the p-GaN area 15a, and the electric resistance is higher in the high resistance area 15b than in the p-GaN area 15a.

### Second Embodiment

### Manufacturing Method of Semiconductor Device

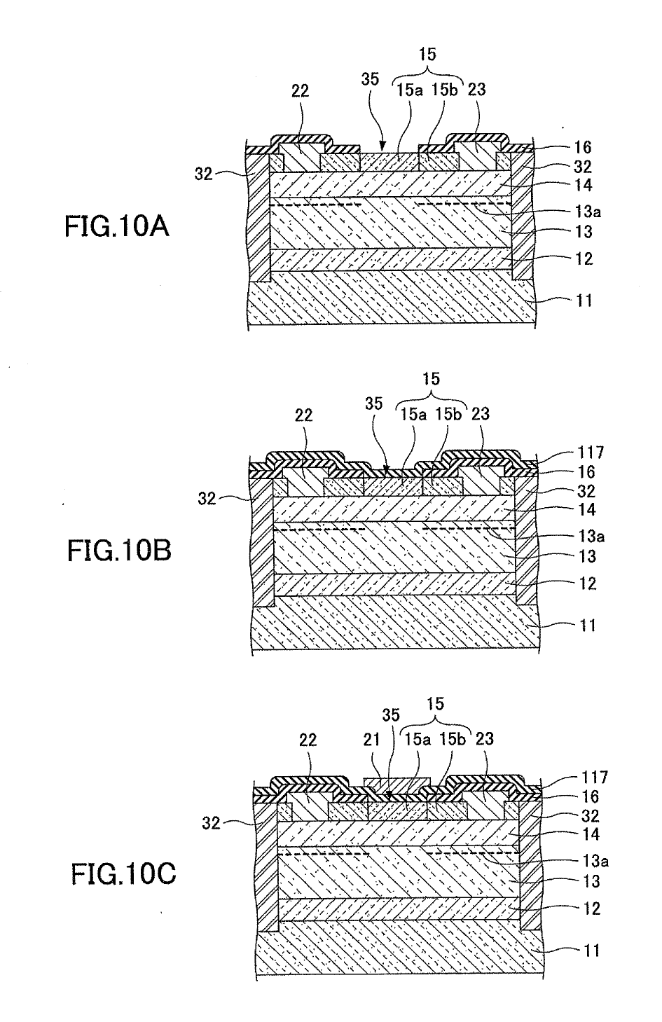

Next, a description is given of a manufacturing method of the semiconductor device according to the present embodiment with reference to FIGS. 10A through 10C. The manufacturing method of the semiconductor device according to the present embodiment is the same as the manufacturing method of the semiconductor device according to the first embodiment in terms of the procedures illustrated in FIGS. 6A through 8B. The procedure of FIG. 10A corresponds to that of FIG. 8B.

In FIG. 10B, the insulating film 117 that is the gate insulating film is formed on the passivation film 16 and the Mg doped GaN layer 15 is exposed at the opening 35. The insulating film 117 is formed by, for example, ALD (Atomic Layer Deposition). In the present embodiment, the insulating film 117 is formed with an oxidized aluminum having a thickness of 30 nm.

Next, as illustrated in FIG. 100, the gate electrode 21 is formed. Specifically, photoresist is applied on the surface of the insulating film 117, and exposure and developing are performed with an exposing device, thereby forming a resist pattern (not illustrated) having an opening in the area where the gate electrode 21 is to be formed. This resist pattern is formed so that the position of the p-GaN area 15a is below the opening of the resist pattern via the insulating film 117. Subsequently, by vacuum deposition, a laminated metal film is formed with Ni/Au, and then by dipping the laminated metal film in an organic solvent, the metal film formed on the resist pattern is removed by being lifted off together with the resist pattern. Accordingly, the gate electrode 21 is formed with a Ni/Au laminated metal film. As described above, the gate electrode 21 is formed via the insulating film 117 on the p-GaN area 15a in the Mg doped GaN layer 15 on which the dielectric mask 31 had been formed. The Ni/Au laminated metal film is formed so that Ni has a thickness of approximately 30 nm and Au has a thickness of approximately 400 nm.

As described above, the semiconductor device according to the present embodiment is manufactured. In the semiconductor device according to the present embodiment, the insulating film 117 that becomes a gate insulating film is formed, and therefore the gate leak current is reduced.

Contents other than the above are the same as those of the first embodiment.

### Third Embodiment

Next, a description is given of a third embodiment. The present embodiment is relevant to a method of manufacturing the semiconductor device according to the first embodiment, which is different from the manufacturing method of the first embodiment.

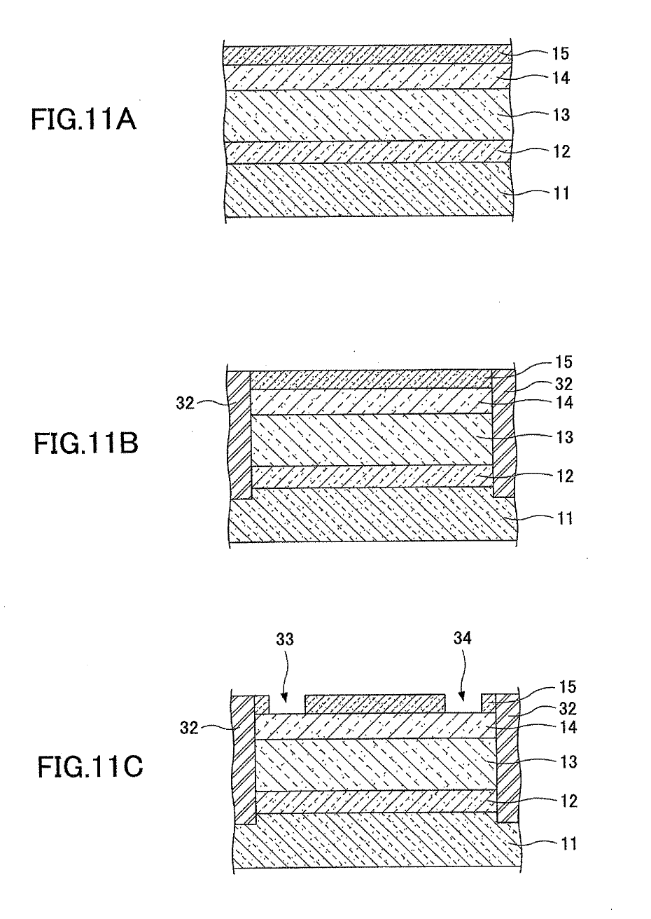

A description is given of the manufacturing method of the semiconductor device according to the third embodiment, with reference to FIGS. 11A through 13.

First, as illustrated in FIG. 11A, on the substrate 11, nitride semiconductor layers including the buffer layer 12, the electron transit layer 13, the electron supply layer 14, and the Mg doped GaN layer 15 are formed by epitaxial growth by a MOVPE (Metal Organic Vapor Phase Epitaxy) method. In the present embodiment, the buffer layer 12 is formed with AlN, the electron transit layer 13 is formed with GaN, and the electron supply layer 14 is formed with AlGaN.

When forming the nitride semiconductor layers by MOVPE, TMA (trimethyl aluminium) is used as the raw material gas of Al, TMG (trimethyl gallium) is used as the raw material gas of Ga, and NH₃ (ammonia) is used as the raw material gas of N. Furthermore, Cp₂Mg (cyclopentadienyl magnesium) is used as the raw material gas of Mg. The raw material gas described above is supplied to a reacting furnace of a MOVPE device by using hydrogen (H₂) as carrier gas.

The ammonia gas supplied when forming the nitride semiconductor layers is supplied by a flow rate of 100 sccm through 10000 sccm, the growth pressure when the nitride semiconductor layer is formed is 50 Torr through 300 Torr, and the growth temperature is 1000° C. through 1200° C. The nitride semiconductor layers may be formed by MBE instead of MOVPE.

As the substrate 11, for example, a sapphire substrate, a Si substrate, and a SiC substrate may be used. In the present embodiment, a SiC substrate is used as the substrate 11. The buffer layer 12 is formed with AIN having a thickness of 0.1 μm. The electron transit layer 13 is formed with GaN having a thickness of 2 μm.

The electron supply layer 14 is formed with AlGaN having a thickness of 20 nm, which is expressed as AlₓGa₁₋ₓN, where X is 0.1 through 0.3. The electron supply layer 14 may be i-AlGaN or n-AlGaN. When forming n-AlGaN, Si is doped as an impurity element, so that the density of Si is 1×10¹⁸ cm⁻³ through 1×10²⁰ cm⁻³, for example 1×10¹⁹ cm⁻³. The raw material gas of Si, is for example, SiH₄.

The Mg doped GaN layer 15 has a thickness of 5 nm through 150 nm, which is formed with GaN doped with Mg as the impurity element, so that the density of the impurity element is 5×10¹⁸ cm⁻³ through 5×10²⁰ cm⁻³. In the present embodiment, the Mg doped GaN layer 15 has a thickness of 50 nm, and is doped with Mg as the impurity element so that the density of the impurity element is 1×10¹⁹ cm⁻³.

After forming the nitride semiconductor layers by MOVPE, a heating process is performed with a temperature of, for example, 400° C. through 1000° C., in a nitride atmosphere. Accordingly, the Mg doped GaN layer 15 is activated. By performing a heating process in a nitride atmosphere as described above, the hydrogen components included in the Mg doped GaN layer 15 are discharged and the Mg doped GaN layer 15 is activated, so that the Mg doped GaN layer 15 becomes a p-type.

Next, as illustrated in FIG. 11B, an element separation area 32 is formed. Specifically, photoresist is applied to the surface of the Mg doped GaN layer 15, and exposure and developing are performed with an exposing device, thereby forming a resist pattern (not illustrated) having an opening in the area where the element separation area 32 is to be formed. Subsequently, by ion-implanting Ar in the nitride semiconductor layers in the area where the resist pattern is not formed, it is possible to form the element separation area 32 on the surfaces of the nitride semiconductor layers and the substrate 11. Subsequently, the resist pattern is removed with an organic solvent.

Next, as illustrated in FIG. 11C, the Mg doped GaN layer 15 is removed from the areas where the source electrode 22 and the drain electrode 23 are formed to be, so that openings 33 and 34 are formed. Specifically, photoresist is applied on the surface of the Mg doped GaN layer 15, and exposure and developing are performed with an exposing device, thereby forming a resist pattern (not illustrated) having openings in the areas where the openings 33 and 34 are to be formed. Subsequently, by performing dry etching such as RIE, the Mg doped GaN layer 15 is removed from areas where the resist pattern is not formed, so that the openings 33 and 34 are formed. At this time, the dry etching may be performed by using chlorinated gas such as Cl₂ as etching gas to completely remove the Mg doped GaN layer 15 in the areas where the resist pattern is not formed. Furthermore, part of the surface of the electron supply layer 14 may also be removed. Subsequently, the resist pattern is removed with an organic solvent.

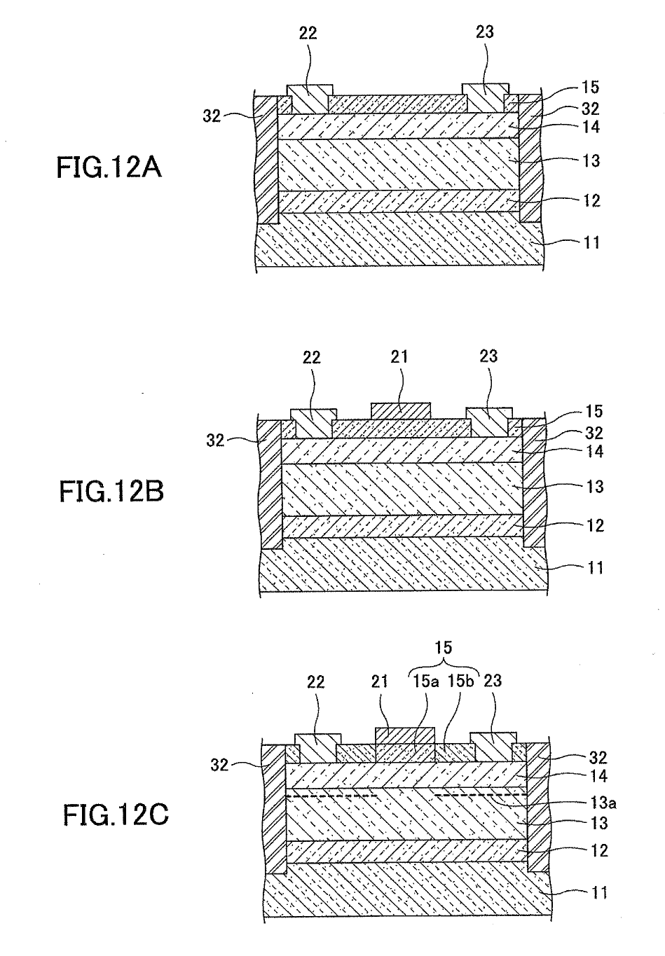

Next, as illustrated in FIG. 12A, the source electrode 22 and the drain electrode 23 are formed in the openings 33 and 34. Specifically, photoresist is applied on the Mg doped GaN layer 15 with the openings 33 and 34, and exposure and developing are performed with an exposing device, thereby forming a resist pattern (not illustrated) having openings in the area where the source electrode 22 and the drain electrode 23 are to be formed. This resist pattern is formed by matching the positions of the openings of the resist pattern with the openings 33 and 34. Subsequently, by vacuum deposition, a laminated metal film is formed with Ti/Al, and then by dipping the laminated metal film in an organic solvent, the metal film formed on the resist pattern is removed by being lifted off together with the resist pattern. Accordingly, the source electrode 22 and the drain electrode 23 are formed, in which Ti/Al is laminated. In the laminated metal layer formed with Ti/Al, Ti has a thickness of approximately 20 nm, and Al has a thickness of approximately 200 nm. Subsequently, for example, a heating process is performed at a temperature of approximately 550 ° C. in a nitride atmosphere, and the source electrode 22 and the drain electrode 23 are made to contact the electron supply layer 14 by Ohmic Contact.

Next, as illustrated in FIG. 12B, the gate electrode 21 is formed. Specifically, photoresist is applied on the surface of the Mg doped GaN layer 15, and exposure and developing are performed with an exposing device, thereby forming a resist pattern (not illustrated) having an opening in the area where the gate electrode 21 is to be formed. Subsequently, by vacuum deposition, a laminated metal film is formed with Ni/Au, and then by dipping the laminated metal film in an organic solvent, the metal film formed on the resist pattern is removed by being lifted off together with the resist pattern. Accordingly, the gate electrode 21 is formed with the laminated metal film made of Ni/Au. The laminated metal film made of Ni/Au is formed so that the thickness of Ni is approximately 30 nm and the thickness of Au is approximately 400 nm.

Next, as illustrated in FIG. 12C, a heating process is performed with a temperature of greater than or equal to 400° C., in an atmosphere of H₂ or NH₃. Accordingly, in the area where the gate electrode 21 is not formed so that the Mg doped GaN layer 15 is exposed, H₂ or H in NH₃ enters the Mg doped GaN layer 15 and diffuses. As described above, in the Mg doped GaN layer 15, H diffuses in the area where the gate electrode 21 is not formed, and the diffused H (hydrogen) bonds with Mg and becomes Mg—H, and therefore the Mg does not function as an accepter and the resistance increases. Therefore, in the Mg doped GaN layer 15, the high resistance area 15b with high resistance where the gate electrode 21 is not formed and the gate electrode 21 are formed, and the p-GaN area 15a that is maintained in an activated state where H has not entered is also formed.

As described above, by forming the high resistance area 15b in the Mg doped GaN layer 15, it is possible to form the 2DEG 13a in the electron transit layer 13 near the interface between the electron transit layer 13 and the electron supply layer 14, without decreasing the electron density immediately below the high resistance area 15b. In the 2DEG 13a formed as described above, electrons disappear immediately below the p-GaN area 15a of the Mg doped GaN layer 15.

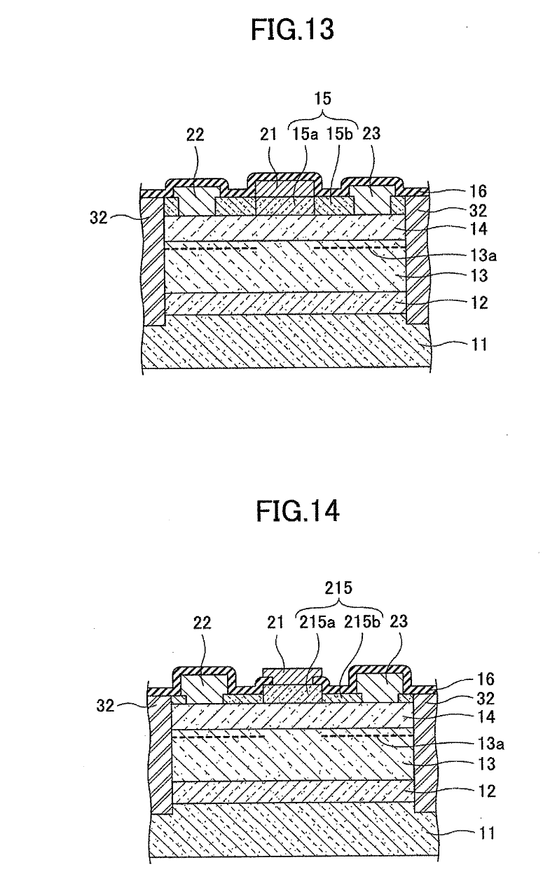

Next, as illustrated in FIG. 13, the passivation film 16 is formed on the Mg doped GaN layer 15. The passivation film 16 is formed by forming SiN having a thickness of 200 nm by CVD.

Contents other than the above are the same as those of the first embodiment.

### Fourth Embodiment

### Semiconductor Device

Next, a description is given of a semiconductor device according to a fourth embodiment. In the semiconductor device according to the present embodiment, as illustrated in FIG. 14, a Mg doped GaN layer 215 is formed on the electron supply layer 14. In the Mg doped GaN layer 215, a p-GaN area 215a that is a p-type area and a high resistance area 215b are formed, and the p-GaN area 215a is formed immediately below the gate electrode 21. In the Mg doped GaN layer 215, the hydrogen density is decreased as described below in the p-GaN area 215a. Accordingly, the Mg doped GaN layer 215 is activated to a p-type by the doped Mg. However, in the high resistance area 215b, the hydrogen density is high and Mg is bound with H, and therefore the resistance is high.

Thus, in the electron transit layer 13, near the interface between the electron transit layer 13 and the electron supply layer 14, a 2DEG 13a is formed. However, it is possible to make the electrons disappear only immediately below the p-GaN area 215a, without decreasing the density of electrons immediately below the high resistance area 215b. That is to say, it is possible to form the 2DEG 13a in which electrons are made to disappear only immediately below the gate electrode 21, without decreasing the density of electrons immediately below the area where the gate electrode 21 is not formed. Accordingly, in the semiconductor device according to the present embodiment, a normally-off state is attained without increasing the on-resistance. In the semiconductor device according to the present embodiment, an element separation area 32 for separating the respective elements is formed, from the surface of the substrate 11 through the buffer layer 12, the electron transit layer 13, the electron supply layer 14, and the Mg doped GaN layer 15.

In the present embodiment, in the Mg doped GaN layer 215, the high resistance area 215b is thinner than the p-GaN area 215a. By making the high resistance area 215b thin, it is possible to reduce the time taken to increase the resistance of the high resistance area 215b, and to prevent the hydrogen from diffusing in the p-GaN area 215a. Therefore, the semiconductor device is manufactured with high yield. As described above, in the semiconductor device according to the present embodiment, in the Mg doped GaN layer 215, the hydrogen density is higher in the high resistance area 215b than in the p-GaN area 215a, and the electric resistance is higher in the high resistance area 215b than in the p-GaN area 215a.

### Fourth Embodiment

### Manufacturing Method of Semiconductor Device

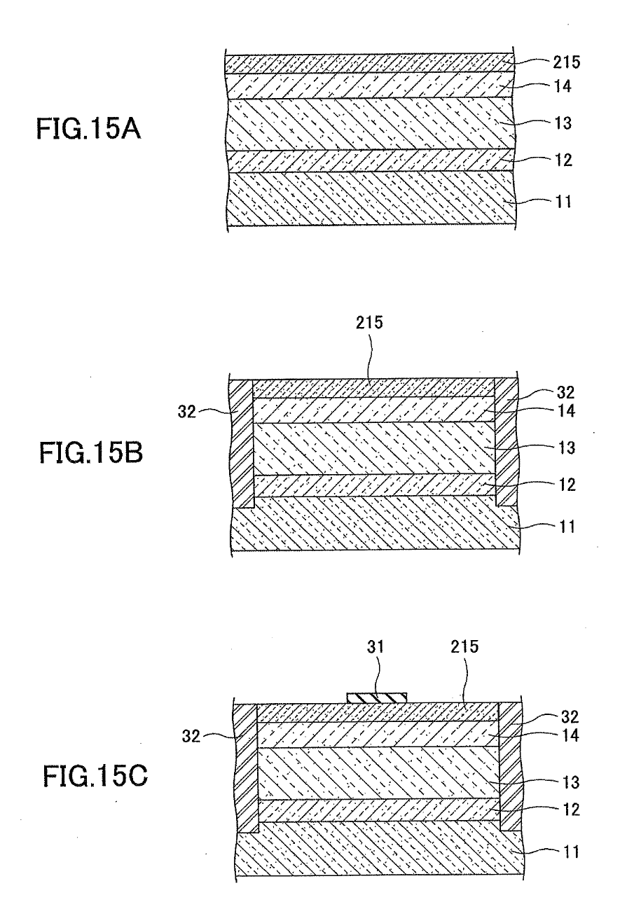

Next, a description is given of a manufacturing method of a semiconductor device according to a fourth embodiment, with reference to FIGS. 15A through 18.

First, as illustrated in FIG. 15A, on the substrate 11, nitride semiconductor layers including the buffer layer 12, the electron transit layer 13, the electron supply layer 14, and the Mg doped GaN layer 15 are formed by epitaxial growth by a MOVPE (Metal Organic Vapor Phase Epitaxy) method. In the present embodiment, the buffer layer 12 is formed with AlN, the electron transit layer 13 is formed with GaN, and the electron supply layer 14 is formed with AlGaN.

When forming the nitride semiconductor layers by MOVPE, TMA (trimethyl aluminium) is used as the raw material gas of Al, TMG (trimethyl gallium) is used as the raw material gas of Ga, and NH₃ (ammonia) is used as the raw material gas of N. Furthermore, Cp₂Mg (cyclopentadienyl magnesium) is used as the raw material gas of Mg. The raw material gas described above is supplied to a reacting furnace of a MOVPE device by using hydrogen (H₂) as carrier gas.

The ammonia gas supplied when forming the nitride semiconductor layers is supplied by a flow rate of 100 sccm through 10000 sccm, the growth pressure when the nitride semiconductor layer is formed is 50 Torr through 300 Torr, and the growth temperature is 1000° C. through 1200° C. The nitride semiconductor layers may be formed by MBE instead of MOVPE.

As the substrate 11, for example, a sapphire substrate, a Si substrate, and a SiC substrate may be used. In the present embodiment, a SiC substrate is used as the substrate 11. The buffer layer 12 is formed with AIN having a thickness of 0.1 μm. The electron transit layer 13 is formed with GaN having a thickness of 2 μm.

The electron supply layer 14 is formed with AlGaN having a thickness of 20 nm, which is expressed as AlₓGa₁₋ₓN, where X is 0.1 through 0.3. The electron supply layer 14 may be i-AlGaN or n-AlGaN. When forming n-AlGaN, Si is doped as an impurity element, so that the density of Si is 1×10¹⁸ cm⁻³ through 1×10²⁰ cm⁻³, for example 1×10¹⁹ cm⁻³. The raw material gas of Si, is for example, SiH₄.

The Mg doped GaN layer 215 has a thickness of 5 nm through 150 nm, which is formed with GaN doped with Mg as the impurity element, so that the density of the impurity element is 5×10¹⁸ cm⁻³ through 5×10²⁰ cm⁻³. In the present embodiment, the Mg doped GaN layer 215 has a thickness of 50 nm, and is doped with Mg as the impurity element so that the density of the impurity element is 1×10¹⁹ cm⁻³.

After forming the nitride semiconductor layers by MOVPE, a heating process is performed with a temperature of, for example, 400° C. through 1000° C., in a nitride atmosphere. Accordingly, the Mg doped GaN layer 215 is activated. By performing a heating process in a nitride atmosphere as described above, the hydrogen components included in the Mg doped GaN layer 215 are discharged and the Mg doped GaN layer 215 is activated, so that the Mg doped GaN layer 215 becomes a p-type.

Next, as illustrated in FIG. 15B, an element separation area 32 is formed. Specifically, photoresist is applied to the surface of the Mg doped GaN layer 215, and exposure and developing are performed with an exposing device, thereby forming a resist pattern (not illustrated) having an opening in the area where the element separation area 32 is to be formed. Subsequently, by ion-implanting Ar in the nitride semiconductor layers in the area where the resist pattern is not formed, it is possible to form the element separation area 32 on the surfaces of the nitride semiconductor layers and the substrate 11. Subsequently, the resist pattern is removed with an organic solvent.

Next, as illustrated in FIG. 15C, on the surface of the Mg doped GaN layer 215, a dielectric mask 31 is formed in the area where the gate electrode 21 is to be formed. Specifically, on the surface of the Mg doped GaN layer 215, a dielectric film such as SiN or SiO₂ is formed, photoresist is applied on the dielectric film, and exposure and developing are performed with an exposing device, thereby forming a resist pattern (not illustrated) in the area where the gate electrode 21 is to be formed. Subsequently, the dielectric film in the area where the resist pattern is not formed is removed by performing wet etching using fluorine, thereby forming the dielectric mask 31 formed with SiN or SiO₂. Subsequently, the resist pattern is removed with an organic solvent.

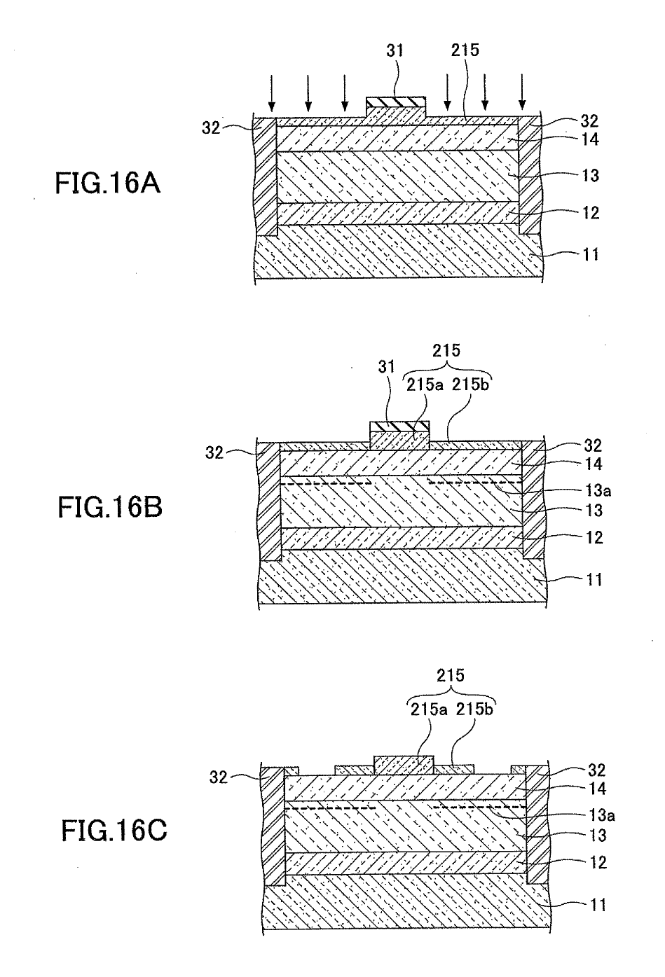

Next, as illustrated in FIG. 16A, by performing dry etching such as RIE, part of the Mg doped GaN layer 215 in the area where the dielectric mask 31 is not formed is removed, so that the thickness of the Mg doped GaN layer 215 is reduced in this area. At this time, the Mg doped GaN layer 215 in the area where the dielectric mask 31 is not formed is etched so as to have a thickness that is approximately half that of the Mg doped GaN layer 215 in the area where the dielectric mask 31 is formed.

Next, as illustrated in FIG. 16B, a heating process is performed with a temperature of greater than or equal to 400° C., in an atmosphere of H₂ or NH₃. Accordingly, in the area where the dielectric mask 31 is not formed such that the Mg doped GaN layer 215 is exposed, H₂ or H in NH₃ enters the Mg doped GaN layer 215 and diffuses. As described above, in the Mg doped GaN layer 215, H diffuses in the area where the dielectric mask 31 is not formed, and the diffused H (hydrogen) bonds with Mg and becomes Mg-H, and therefore the Mg does not function as an accepter and the resistance increases. Therefore, in the Mg doped GaN layer 215, the high resistance area 215b with high resistance where the dielectric mask 31 is not formed and the dielectric mask 31 are formed, and the p-GaN area 215a that is maintained in an activated state where H has not entered is also formed.

As described above, by forming the high resistance area 215b in the Mg doped GaN layer 215, it is possible to form the 2DEG 13a in the electron transit layer 13 near the interface between the electron transit layer 13 and the electron supply layer 14, without decreasing the electron density immediately below the high resistance area 215b. In the 2DEG 13a formed as described above, electrons disappear immediately below the p-GaN area 215a of the Mg doped GaN layer 215.

Next, as illustrated in FIG. 16C, after removing the dielectric mask 31, the Mg doped GaN layer 215 in the areas where the source electrode 22 and the drain electrode 23 are formed is removed, so that openings 33 and 34 are formed. Specifically, photoresist is applied on the surface of the Mg doped GaN layer 215, and exposure and developing are performed with an exposing device, thereby forming a resist pattern (not illustrated) having openings in the areas where the openings 33 and 34 are to be formed. Subsequently, by performing dry etching such as RIE, the Mg doped GaN layer 215 is removed from areas where the resist patter is not formed, so that the openings 33 and 34 are formed. The dry etching at this time may be performed by using chlorinated gas such as Cl₂ as etching gas to completely remove the Mg doped GaN layer 215 in the area where the resist pattern is not formed. Furthermore, part of the surface of the electron supply layer 14 may also be removed. Subsequently, the resist pattern is removed with an organic solvent.

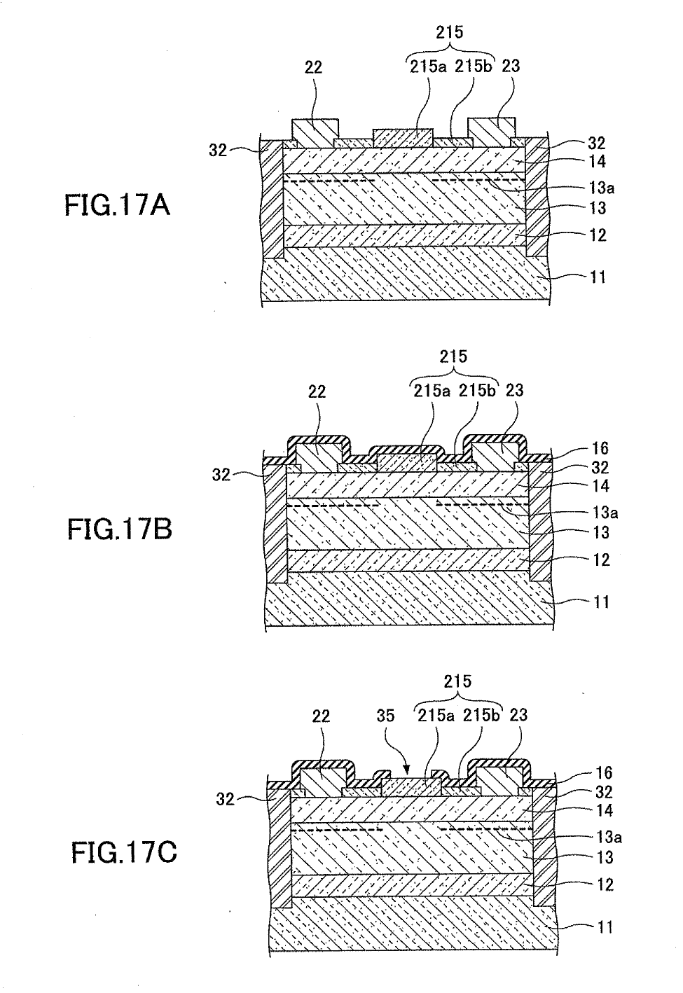

Next, as illustrated in FIG. 17A, the source electrode 22 and the drain electrode 23 are formed in the openings 33 and 34. Specifically, photoresist is applied on the Mg doped GaN layer 215 with the openings 33 and 34, and exposure and developing are performed with an exposing device, thereby forming a resist pattern (not illustrated) having openings in the area where the source electrode 22 and the drain electrode 23 are to be formed. This resist pattern is formed by matching the positions of the openings of the resist pattern with the openings 33 and 34. Subsequently, by vacuum deposition, a laminated metal film is formed with Ti/Al, and then by dipping the laminated metal film in an organic solvent, the metal film formed on the resist pattern is removed by being lifted off together with the resist pattern. Accordingly, the source electrode 22 and the drain electrode 23 are formed, in which Ti/Al is laminated. In the laminated metal layer formed with Ti/Al, Ti has a thickness of approximately 20 nm, and Al has a thickness of approximately 200 nm. Subsequently, for example, a heating process is performed at a temperature of approximately 550° C. in a nitride atmosphere, and the source electrode 22 and the drain electrode 23 are made to contact the electron supply layer 14 by Ohmic Contact.

Next, as illustrated in FIG. 17B, the passivation film 16 is formed on the Mg doped GaN layer 215. The passivation film 16 is formed by forming SiN having a thickness of 200 nm by CVD.

Next, as illustrated in FIG. 17C, the passivation film 16 is removed from the area where the gate electrode 21 is formed, and an opening 35 is formed. The opening 35 is formed in the area where the gate electrode 21 is to be formed. Specifically, photoresist is applied on the surface of the passivation film 16, and exposure and developing are performed with an exposing device, thereby forming a resist pattern (not illustrated) having an opening in the area where the opening 35 is to be formed. Subsequently, by performing dry etching such as RIE, or by performing wet etching with Buffered Hydrogen Fluoride, the passivation film 16 in the area where the resist pattern is not formed is removed, so that the opening 35 is formed. Subsequently, the resist pattern is removed with an organic solvent. The opening 35 that is formed preferably substantially matches the p-GaN area 215a, but may be larger or smaller than the p-GaN area 215a.

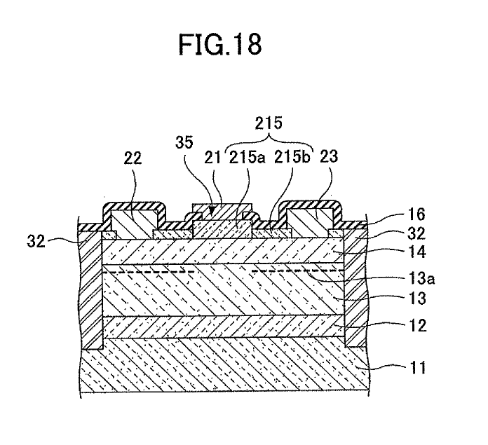

Next, as illustrated in FIG. 18, the gate electrode 21 is formed. Specifically, photoresist is applied on the surface of the passivation film 16 in which the opening 35 is formed, and exposure and developing are performed with an exposing device, thereby forming a resist pattern (not illustrated) having an opening in the area where the gate electrode 21 is to be formed. The resist pattern is formed by matching the position of the opening of the resist pattern with the opening 35. Subsequently, by vacuum deposition, a laminated metal film is formed with Ni/Au, and then by dipping the laminated metal film in an organic solvent, the metal film formed on the resist pattern is removed by being lifted off together with the resist pattern. Accordingly, the gate electrode 21 is formed with the laminated metal film made of Ni/Au. The gate electrode 21 is formed on the p-GaN area 215a in the Mg doped GaN layer 215. The laminated metal film made of Ni/Au is formed so that the thickness of Ni is approximately 30 nm and the thickness of Au is approximately 400 nm.

As described above, the semiconductor device according to the present embodiment is manufactured. In the semiconductor device according to the present embodiment, in the Mg doped GaN layer 215, the high resistance area 215b is thinner than the p-GaN area 215a, and hydrogen is diffused in the high resistance area 215b. Accordingly, hydrogen barely diffuses to the p-GaN area 215a, and therefore it is possible to attain a semiconductor device that is highly uniform with high yield.

### Fifth Embodiment

Next, a description is given of a fifth embodiment. The present embodiment is pertinent to a semiconductor device, a power unit, and a high-frequency amplifier.

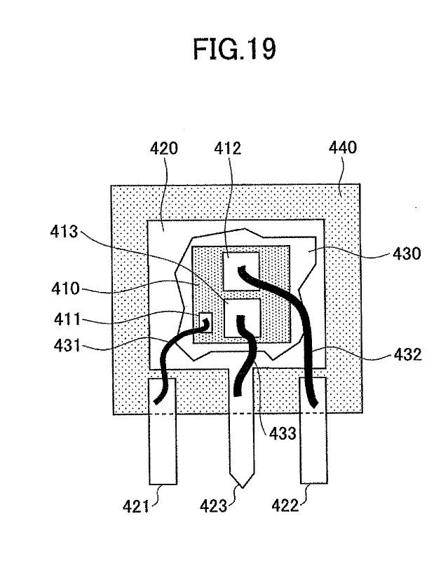

The semiconductor device according to the present embodiment is formed by discretely packaging the semiconductor device. The discretely packaged semiconductor device is described with reference to FIG. 19. FIG. 19 schematically illustrates the inside of the discretely packaged semiconductor device, in which the arrangements of the electrodes are different from those of the first through fourth embodiments.

First, the semiconductor device manufactured according to the first through fourth embodiments is cut by dicing, and a semiconductor chip 410 that is a HEMT made of a GaN system material is formed. The semiconductor chip 410 is fixed on a lead frame 420 by a diatouch agent 430 such as solder. The semiconductor chip 410 corresponds to the semiconductor device according to the first through fourth embodiments.

Next, the gate electrode 411 is connected to a gate lead 421 by a bonding wire 431, the source electrode 412 is connected to a source lead 422 by a bonding wire 432, and the drain electrode 413 is connected to a drain lead 423 by a bonding wire 433. The bonding wires 431, 432, and 433 are formed by a metal material such as Al. Furthermore, in the present embodiment, the gate electrode 411 is a gate electrode pad, which is connected to the gate electrode 21 of the semiconductor device according to the first to fourth embodiments. Furthermore, the source electrode 412 is a source electrode pad, which is connected to the source electrode 22 of the semiconductor device according to the first to fourth embodiments. Furthermore, the drain electrode 413 is a drain electrode pad, which is connected to the drain electrode 23 of the semiconductor device according to the first to fourth embodiments.

Next, resin sealing is performed with mold resin 440 by a transfer mold method. As described above, a discretely packaged semiconductor chip that is a HEMT made of a GaN system material is manufactured.

Next, a description is given of a power unit and a high-frequency amplifier according to the present embodiment. The power unit and the high-frequency amplifier according to the present embodiment use any one of the semiconductor devices according to the first through fourth embodiments.

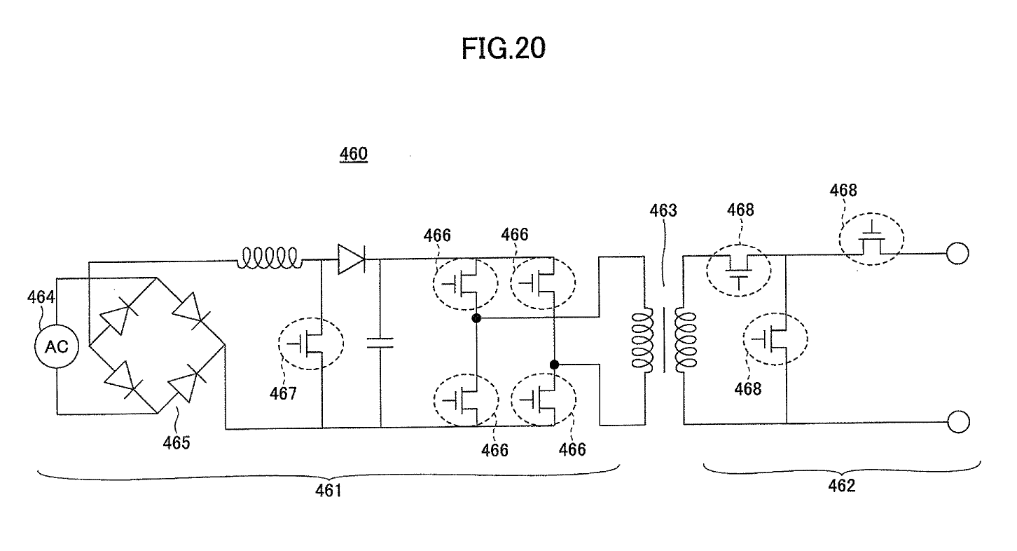

First, with reference to FIG. 20, a description is given of the power unit according to the present embodiment. A power unit 460 according to the present embodiment includes a high voltage primary side circuit 461, a low voltage secondary side circuit 462, and a transformer 463 disposed between the high voltage primary side circuit 461 and the low voltage secondary side circuit 462. The high voltage primary side circuit 461 includes an AC (alternating-current) source 464, a so-called bridge rectifier circuit 465, plural switching elements (four in the example of FIG. 20) 466, and one switching element 467. The low voltage secondary side circuit 462 includes plural switching elements 468 (three in the example of FIG. 20). In the example of FIG. 20, the semiconductor device according to the first through fourth embodiments is used as the switching elements 466 and the switching element 467 of the high voltage primary side circuit 461. The switching elements 466 and 467 of the primary side circuit 461 are preferably normally-off semiconductor devices. Furthermore, switching elements 468 used in the low voltage secondary side circuit 462 are typical MISFET (Metal Insulator Semiconductor Field Effect Transistor) made of silicon.

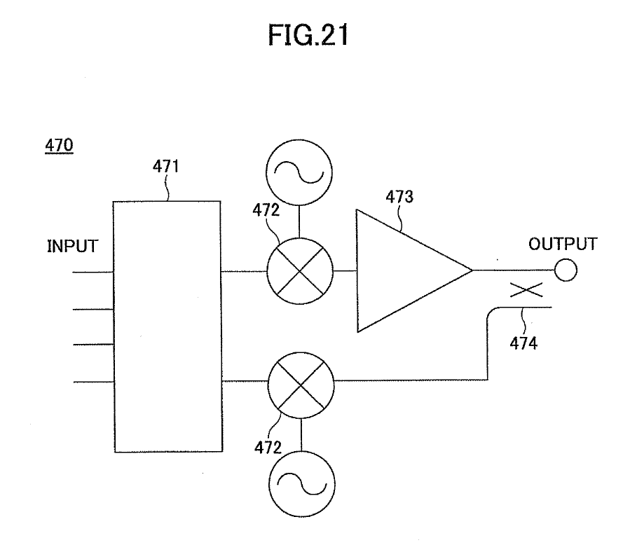

Next, with reference to FIG. 21, a description is given of the high-frequency amplifier according to the present embodiment. A high-frequency amplifier 470 according to the present embodiment may be applied to a power amplifier of a base station of mobile phones. The high-frequency amplifier 470 includes a digital predistortion circuit 471, mixers 472, a power amplifier 473, and a directional coupler 474. The digital predistortion circuit 471 offsets the non-linear strains of input signals. The mixers 472 mix the input signals, whose non-linear strains have been offset, with AC signals. The power amplifier 473 amplifies the input signals that have been mixed with the AC signals. In the example of FIG. 21, the power amplifier 473 includes the semiconductor device according to the first through fourth embodiments. The directional coupler 474 monitors input signals and output signals. In the circuit of FIG. 21, for example, the switch may be switched so that output signals are mixed with AC signals by the mixers 472 and sent to the digital predistortion circuit 471.

According to an aspect of the embodiments, a semiconductor device and a method of manufacturing a semiconductor device are provided, by which a normally-off state is attained without increasing the on-resistance in a semiconductor device using a nitride semiconductor such as GaN as the semiconductor material.

The semiconductor device and a method of manufacturing a semiconductor device are not limited to the specific embodiments described herein, and variations and modifications may be made without departing from the scope of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

1. A semiconductor device comprising:
a first semiconductor layer formed on a substrate;
a second semiconductor layer formed on the first semiconductor layer;
a third semiconductor layer formed on the second semiconductor layer;
a gate electrode formed on the third semiconductor layer; and
a source electrode and a drain electrode formed on the second semiconductor layer, wherein
the third semiconductor layer is formed with a semiconductor material doped with a p-type impurity element, and
in the third semiconductor layer, a p-type area is formed immediately below the gate electrode, and a high resistance area having a higher resistance than the p-type area is formed in an area other than the p-type area.

2. The semiconductor device according to claim 1, wherein in the high resistance area, the p-type impurity element is bound with hydrogen.

3. The semiconductor device according to claim 1, wherein
in the third semiconductor layer, a density of hydrogen in the high resistance area is higher than a density of hydrogen in the p-type area.

4. The semiconductor device according to claim 1, wherein
the p-type impurity element is Mg.

5. The semiconductor device according to claim 1, wherein
a density of Mg in the third semiconductor layer is 5×10¹⁸ cm⁻³ through 5×10²⁰ cm⁻³.

6. The semiconductor device according to claim 1, wherein
an insulating film is formed between the third semiconductor layer and the gate electrode.

7. The semiconductor device according to claim 1, wherein
a thickness of the third semiconductor layer in the high resistance area is less than a thickness of the third semiconductor layer in the p-type area.

8. The semiconductor device according to claim 1, wherein
the first semiconductor layer, the second semiconductor layer, and the third semiconductor layer are formed with a nitride semiconductor.

9. The semiconductor device according to claim 1, wherein
the semiconductor material in the third semiconductor layer is a material including GaN.

10. The semiconductor device according to claim 1, wherein
the first semiconductor layer is formed with a material including GaN.

11. The semiconductor device according to claim 1, wherein
the second semiconductor layer is formed with a material including AlGaN.

12. A power unit comprising:
the semiconductor device according to claim 1.

13. An amplifier comprising:
the semiconductor device according to claim 1.

14. A method of manufacturing a semiconductor device, the method comprising:
sequentially forming a first semiconductor layer, a second semiconductor layer, and a third semiconductor layer including a p-type impurity element on a substrate;
performing a heating process in a nitrogen atmosphere after forming the third semiconductor layer;
forming a dielectric mask in an area on the third semiconductor layer where a gate electrode is to be formed;
performing a heating process in a hydrogen atmosphere or an ammonia atmosphere after forming the dielectric mask; and
removing the dielectric ask and forming the gate electrode in the area where the dielectric mask has been formed and removed,

15. The method according to claim 14, further comprising:
forming an insulating film on the third semiconductor layer after the performing of the heating process in the hydrogen atmosphere or the ammonia atmosphere; and
forming, via the insulating film, the gate electrode in the area where the dielectric mask has been formed and removed,

16. The method according to claim 14, further comprising:
removing part of the third semiconductor layer in an area where the dielectric mask is not formed, after the forming of the dielectric mask; and
performing the heating process in the hydrogen atmosphere or the ammonia atmosphere after the removing of the part of the third semiconductor layer.

17. A method of manufacturing a semiconductor device, the method comprising:
sequentially forming a first semiconductor layer, a second semiconductor layer, and a third semiconductor layer including a p-type impurity element on a substrate;
performing a heating process in a nitrogen atmosphere after forming the third. semiconductor layer;
forming a gate electrode on the third semiconductor layer; and
performing a heating process in a hydrogen atmosphere or an ammonia atmosphere after forming the gate electrode.

18. The method according to claim 14, wherein
the p-type impurity element is Mg.

19. The method according to claim 14, wherein
the first semiconductor layer, the second semiconductor layer, and the third semiconductor layer are formed by MOVPE (Metal Organic Vapor Phase Epitaxy).

20. The method according to claim 14, further comprising:
forming a source electrode and a drain electrode in contact with the second semiconductor layer.
